(19) United States
(12) Patent Application Publication
(10) Pub. No.: US 2009/0134522 A1
(43) Pub. Date: May 28, 2009

(54) Micro-Electromechanical System Memory Device and Method of Making the Same

(75) Inventors: Charles Gordon Smith, Cambridge (GB); Robert Kazinczi, Helmond (NL); Robertus P. Van Kampen, Den Bosch (NL)

Correspondence Address: Cavendish Kinetics;attn: Legal Dept., 3833 North First Street, San Jose, CA, 95134, US

(73) Assignee: CAVENDISH KINETICS LTD., SAN JOSE, CA (US)

(21) Appl. No.: 12/085,506

(22) PCT Filed: Nov. 22, 2006
(86) PCT No.: PCT/GB2006/004353

§ 371 Date: May 22, 2008

(30) Foreign Application Priority Data
Nov. 22, 2005 (GB) V0523645.0

(51) Int. Cl. H01L 29/45; H01L 21/441

(52) U.S. Cl. 257/769; 438/666; 257/E21.477; 257/E29.143

(57) ABSTRACT

A method of manufacturing a non-volatile memory bitcell comprises the steps of depositing a first layer of conductive material on a substrate and patterning and etching the first layer of conductive material to form three non-linearly disposed electrodes. The method also comprises the steps of depositing a first layer of sacrificial material on the electrodes and the substrate and providing an elongate cantilever structure on the first layer of sacrificial material such that the cantilever structure and at least a portion of each electrode overlap each other. The method also includes the steps of depositing a second layer of sacrificial material on the cantilever structure and the first layer of sacrificial material and providing a capping layer on the second layer of sacrificial material and providing holes in the capping layer such that at least a portion of the second layer of sacrificial material is exposed. Finally, the method provides the step of removing the first and second layers of sacrificial material through the holes provided in the capping layer, thereby defining a cavity in which the cantilever structure is suspended.

The present invention relates to micro-electromechanical structures for use in, for example, semiconductor devices. Micro-electromechanical system (MEMS) devices have significant potential in a variety of fields such as telecommunications, sensing, optics and micro-fluidics.

A MEMS switch, for example, incorporates a moveable micro-electromechanical structure, such as a cantilever arm, which is activated by the influence of electromagnetic fields created by actuating voltages applied to electrodes. The electromagnetic fields move the cantilever structure between two stable positions in order to provide a bipolar switch. An advantage of micro-electromechanical devices is their suitability for being integrated into conventional integrated circuit (IC) technology. However, a disadvantage of MEMS-based devices is the high voltages required (typically 40V or higher) to actuate the switches, compared with typical IC operating voltages of about 5V or lower. A solution to providing a MEMS-based device with lower voltage requirements is to scale the MEMS device down such that the cantilever arm is made smaller and is therefore easier to actuate.

However, the fabrication of micro-electromechanical devices entails highly complex deposition processes and photo-lithographic procedures. Micro-electromechanical devices and structures are fabricated using silicon-based processing techniques which include bulk micro-machining of silicon or surface micro-machining using sacrificial layer technology. Such technology is commonly used for making free-standing structures, predominantly in the form of conductors interposed between layers of sacrificial material which are chemically released to expose the free-standing structure in a cavity.

Substrate material may include silicon, silicon oxide, glass, or other ceramics. The sacrificial layer material may include semiconductor materials such as silicon, polysilicon, silicon oxide, silicon nitride, glasses like phosphorous silicate glass, polymers, ceramics or any other material that is suitable for precision machining. Standard techniques for releasing the structural layer include dry (plasma) or wet etching of the sacrificial layer(s). In addition to the above, amorphous carbon may be used in combination with the aforementioned metal layers.

Movable micro-electromechanical structures are extremely thin (typically in the order of hundreds of nanometres to a few micrometers thin) and incur a high degree of residual thermo-mechanical stress, either during fabrication or during use, which causes the micro-electromechanical structures to buckle or bend, either temporarily or, in some cases, permanently. The resulting curvatures can reduce the efficiency and/or functionality of the micro-electromechanical device, especially where orientation of the structure relative to the actuating electrodes is critical.

Residual thermal stress presents a major problem in the MEMS field, which sometimes cannot be adequately resolved by tuning the fabrication process. This is especially true for sub-micron micro-electromechanical structures which are used, for example, in radio frequency switches, relays or resonant MEMS chemical detectors.

When the size of a micro-electromechanical structure, such as a cantilever, is critical and sub-micron thin films are used, surface effects (such as oxidation) and fluctuations in the deposition conditions of the film have considerable impact on the characteristics of the device. Surface effects result in gradient stress across the film, which generates curvature in single-clamped cantilever structures. The induced curvature tends to change the actuation or detection properties of the devices, such as the pull-in voltage of a MEMS switch implementing electrostatic actuation.

Accordingly, there is a clear need for a sub-micron MEMS cantilever-based device which minimises the effects of stress-induced curvature.

In order to solve the problems associated with the prior art, the present invention provides a method of manufacturing a non-volatile memory bitcell, the method comprises the steps of:

depositing a first layer of conductive material on a substrate;

patterning and etching the first layer of conductive material to form three non-linearly disposed electrodes;

depositing a first layer of sacrificial material on the electrodes and the substrate;

providing an elongate cantilever structure on the first layer of sacrificial material such that the cantilever structure and at least a portion of each electrode overlap each other;

depositing a second layer of sacrificial material on the cantilever structure and the first layer of sacrificial material;

providing a capping layer on the second layer of sacrificial material and providing holes in the capping layer such that at least a portion of the second layer of sacrificial material is exposed;

removing the first and second layers of sacrificial material through the holes provided in the capping layer, thereby defining a cavity in which the cantilever structure is suspended.

Preferably, the step of providing the elongate cantilever structure further comprises the steps of:

depositing a second layer of conductive material on the first layer of sacrificial material;

patterning and etching the layer of conductive material such that it forms an elongate cantilever structure.

Preferably, the step of patterning and etching the layer of conductive material further comprises the step of:

patterning and etching the layer of conductive material into a U-shaped cantilever structure.

Preferably, the electrodes are made from a group of materials selected from Nickel, Copper, Chromium, Cobalt, Zinc, Iron, Titanium Aluminium Tantalum, Ruthenium, Platinum, Cobalt and alloys or compounds thereof.

Preferably, the sacrificial layer is made from silicon-based materials or carbon-based materials.

Preferably, the layer defining the cantilever structure comprises a group of materials selected from Nickel, copper, Chromium, Cobalt, Zinc, Iron, Titanium, Aluminium, Tantalum, Ruthenium, Platinum, Cobalt and alloys or compounds thereof.

Preferably, the layers of sacrificial material are removed through etching.

The present invention further provides a non-volatile memory bitcell which comprises:

a substrate;

a first, second and third electrode, the electrodes being co-planarly and non-linearly disposed on the substrate;

a cantilever structure disposed such that the cantilever structure and at least a portion of each electrode overlap each other, the non-volatile memory bitcell being arranged such that, in use, the application of a voltage between the first and second electrode pulls at least a portion of the cantilever structure toward the second electrode and the application of a voltage between the first and the third electrode pushes the at least one portion of the cantilever structure away from the second electrode.

Preferably, the non-volatile memory bitcell of claim 8, wherein the cantilever structure is U-shaped.

Preferably, the electrodes are made from a group of materials selected from Nickel, Copper, Chromium, Cobalt, Zinc, Iron, Titanium Aluminium Tantalum, Ruthenium, Platinum, Cobalt and alloys or compounds thereof.

Preferably, the cantilever structure comprises a group of materials selected from Nickel, copper, Chromium, Cobalt, Zinc, Iron, Titanium, Aluminium, Tantalum, Ruthenium, Platinum, Cobalt and alloys or compounds thereof.

As will be appreciated by a person skilled in the art, the present invention provides several advantages over the prior art. One advantage of having a structure according to the present invention is that the distance between it and the pull-in electrode is relatively small and therefore, a lower pull-in voltage is required to switch on the device.

Also, the micro-electromechanical structure of the present invention can swing back and forth between two modes of operation. In a first mode, the device can be operable in a one-time programmable (OTP) mode in, for example, memory applications wherein the first state comprises the micro-electromechanical structure positioned in a free-standing state. In a second state, the influence of electrostatic forces attracts the structure in the free-standing state to a state in which it is in contact with an electrode such that charge transfer can take place there between.

In another mode the device can be operable in a multi-time programmable (MTP) mode in, for example, memory applications or applications which require a fast switch. In this MTP mode the micro-electromechanical structure is free standing while in a second state the structure is pulled in under the influence of electrostatic forces to make contact with an electrode such that charge transfer can take place. In a third state, the contact can be broken under the influence of another electrostatic force.

One advantage of such an MTP switch is that the pull-in and pull-off electrodes are in the same plane. Thus, no extra masking step is required during fabrication in order to provide both an OTP and an MTP device.

Examples of the present invention will now be described with reference to the accompanying drawings, in which:

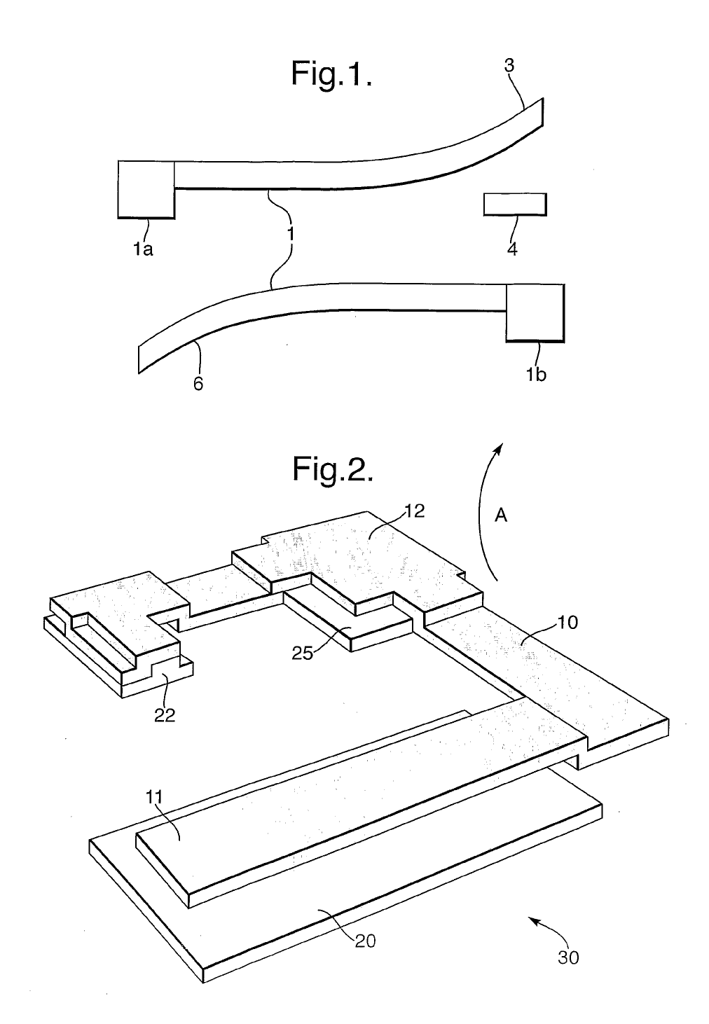

FIG. 1 shows an end view of a prior art micro-electromechanical structure exhibiting post fabrication gradient stress;

FIG. 2 shows a perspective view of an example of a micro-electromechanical structure in accordance with the present invention;

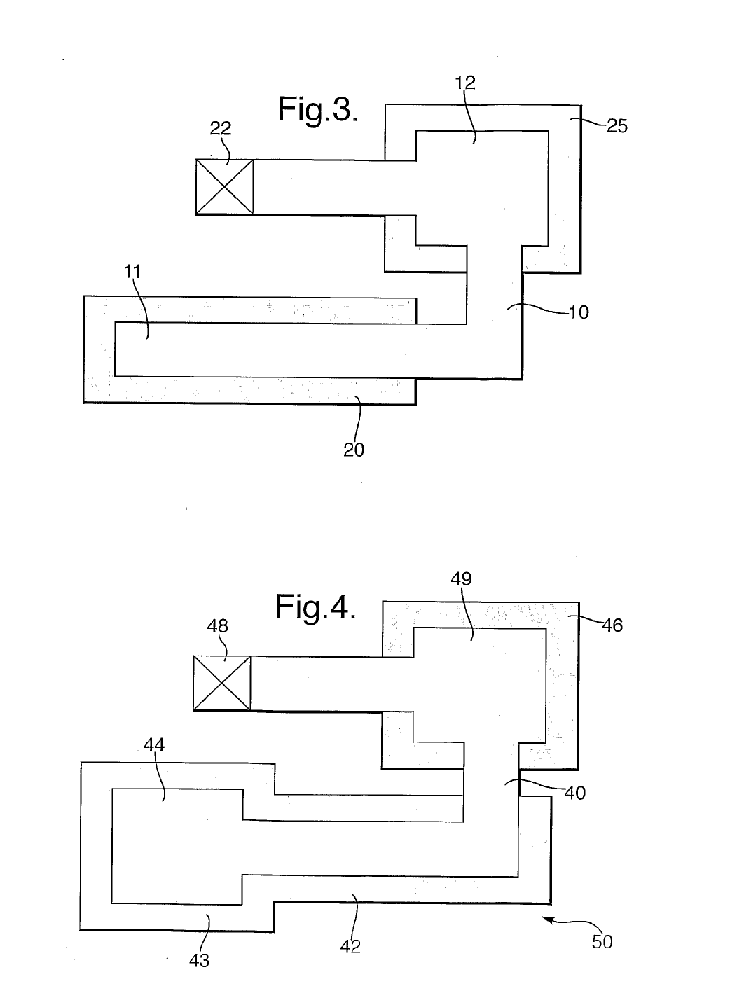

FIG. 3 shows a plan view of the micro-electromechanical structure of FIG. 2; and

FIG. 4 shows a plan view of a micro-electromechanical structure in accordance with a second example of the present invention.

FIG. 1 shows a linear micro-electromechanical structure 1, such as a cantilever formed on a substrate having no applied bias voltage but exhibiting intrinsic post-fabrication thermal residual stresses. FIG. 1a shows an example of a structure having a free end 3 oriented away from an actuating electrode 4, while FIG. 1b shows the micro-electromechanical structure 1 having a downward curvature. In designs according to the prior art, when upward curvature occurs, difficulties may arise in actuating the micro-electromechanical structure so as to bring it into contact with the deflecting electrode situated beneath it. In such a situation, greater actuating voltages are required to effect contact of the cantilever with the underlying electrodes.

Moreover, if the structural material comprises two or more layers, then the coefficient of thermal expansion (CTE) mismatch arising between the different materials composing the micro-electromechanical structure can produce a stress gradient, thereby causing an upward curvature, for example, as the temperature of the structure decreases, having been exposed to elevated fabrication temperatures.

The micro-electromechanical structure and arrangement of the present invention circumvents the stress-induced curvature effects associated with gradient stress induced in conventional linear structures, and therefore sets less exacting requirements on process control.

FIG. 2 shows a perspective view of a micro-electromechanical structure 10, namely a cantilever beam, which can be actuated according to an example of the invention. The micro-electromechanical structure 10 is supported by a first electrode 22 formed on a substrate 30 on which is further disposed a second electrode 20 (known as a pull-in electrode) and a third electrode 25 (known as a pull-off electrode), with the structure 10 being movable selectively with respect to the second electrode 20 and the third electrode 25. The first, second and third electrodes are not linearly arranged.

Now, with reference to FIG. 2, the operation of the micro-electromechanical structure 10 will now be described. When a predetermined pull-in voltage is applied to the second electrode 20, the distal portion 11 (the free end) of the micro-electromechanical structure 10 moves toward the second electrode 20 and comes into contact with the structure 10. This characterises the “ON” state of the device. At least one contact point is required between the structure 10 and the electrode 20 in order to permit the transfer of charges there between.

Movement of the distal portion 11 of the micro-electromechanical structure 10 towards the second electrode 20 by the application of a pull-in voltage induces a corresponding upward movement at the proximal portion 12 of the cantilever structure 10, as shown by arrow A, as a result of a bending moment induced in the structure.

In this mode the device can be operable in a one-time programmable (OTP) mode. Such operation is particularly suited for memory applications where the first state of the device could represent a first state of a memory cell (such as a “non-programmed state” or an “OFF” state) and the second state could represent a second state of the memory cell (such as a “programmed” state or an “ON” state). A variety of adhesive forces (i.e. “stiction”) maintain the distal end 11 of the structure 10 in contact with the electrode 20. Stiction refers to various forces tending to make two surfaces stick together, such as Van der Waals forces, surface tension caused by moisture between the surfaces and/or bonding between surfaces (e.g. through covalent or metallic bonding between the atoms at the two surfaces).

In a mode where the invention uses the third electrode 25 during operation, the device can be operable in a multi-time programmable (MTP) mode. This mode would be particularly suitable for memory deices used in applications where fast switching action is required (e.g. radio frequency applications).

Now, with reference to FIG. 2, the second mode of operation of the device will now be described. While in the “ON” state described above, the micro-electromechanical structure can be switched to an “OFF” state using the pull-off electrode 25. The application of a predetermined voltage to the pull-off electrode 25 induces a stress gradient in the micro-electromechanical structure 10. A bending moment is thereby generated along the length of the structure 10 near the third electrode 25, which in turn causes the structure 10 to bend upwardly in the proximal portion thereof. Once the forces maintaining the contact between the distal end 11 of the structure 10 and the electrode 20 are overcome by the influence of the applied electrostatic forces, the distal end 11 of the structure 10 is released to the “OFF” state in which structure 10 is again supported only by the first electrode 22.

Because of the spacing of electrode 20 and electrode 25 beneath the structure 10, when a pull-in voltage is applied to the second electrode 20, the proximal portion 12 of the micro-electromechanical structure 10 bends upwardly away from the second electrode 25.

The micro-electromechanical structure 10 of the present invention typically has the effect of facilitating the transition of the structure from an “ON” to an “OFF” state, owing to the induction of a bending moment in the structure. In the ON state, the spring force or restoring force of the structure must counteract the “stiction” between the structure and the surface of the electrode.

Preferably the material with which the cantilever is made may permit it to bend sufficiently on application of an actuating voltage while maintaining adequate rigidity to prevent excessive contact with the contact electrode such that the contact area is minimised.

The micro-electromechanical device according to the invention comprises a metallic layer having an intrinsic stress gradient which arises owing to the presence of the bending moment. While the micro-electromechanical structure of the present invention is substantially made from the group of metals such as Nickel, Copper, Chromium, Cobalt, Zinc, Iron, Titanium, Aluminium, Tantalum, their alloys or compounds such as Titanium Nitride or Tantalum Nitride, other suitable materials for the metal layer may include Ruthenium, Platinum or Cobalt and compounds thereof.

The manufacture of such a micro-electromechanical structure entails step by step deposition of layers of the materials along with photolithography steps to form a device on a silicon-based, Gallium-based or any ceramic-based semiconductor substrate having materials that are compatible with the materials from which the micro-electromechanical structure is made. The structure is fabricated using deposition processes including physical vapour deposition (PVD), chemical vapor deposition (CVD) or modifications of such processes such as atomic layer deposition (ALD).

The method of manufacture of the switch arrangement or non-volatile memory arrangement comprises several steps. The first step is that of depositing a first layer of conductive material onto a substrate. The first layer of conductive material may equally be formed from metallic materials or compounds of materials, such as those described above. Then, the first layer of conductive material is patterned and etched into three, non-linearly disposed electrodes. Once this is done, a first layer of sacrificial material is deposited above the patterned electrodes and the substrate. The layer of sacrificial material is then partially patterned and etched in order to open a region above electrode 22 that will subsequently be used to allow structure 10 to make electrical and mechanical contact to electrode 22.

Then a second layer of conductive material is deposited over the first layer of sacrificial material. This second layer of conductive material is then patterned and etched in order to form structure 10. The structure 10 must be patterned and etched such that at least a portion of the resulting structure will cover at least a portion of each non-linearly disposed electrode. One advantageous shape for the structure is substantially that of a “U”, as shown in FIGS. 2 to 4. Once this is done, a second layer of sacrificial material is deposited above the structure 10 and the first layer of sacrificial material.

A final layer of material is then deposited above the second layer of sacrificial material and via holes are etched into the final layer in order to expose at least a portion of the second layer of sacrificial material. Finally, the sacrificial material layers are etched away, thereby defining a cavity in which the structure 10 is suspended.

The sacrificial layers may comprise silicon-based materials such as silicon, polysilicon, silicon oxide, silicon nitride, phosphorous silicate glass, polymers, ceramics, photoresist, foil, spin on dielectric (SOD) or any other suitable material. The polymer materials can include removable polymers such as polyimides. In addition to the above, carbon-based materials such as amorphous carbon may be used. Standard techniques for removing the sacrificial layers include dry (plasma) or wet etching.

Referring now to FIG. 3, the layer forming the electrodes of the deflection means are patterned such that the three electrodes are not linearly disposed. Also, the electrodes substantially overlap (or cover) the corresponding proximal portion 25 and distal portion 20 of the micro-electromechanical structure 10.

Referring now to FIG. 4, in a further example of the present invention, the metal layer defining the micro-electromechanical structure 40 having a proximal portion 49 may be patterned during the fabrication process such that the free end of the structure may have a larger area 44 (distal portion) compared with the rest of the cantilever structure 40. Similarly the first electrode 42 may have a similar or larger area 43 to that of the free end of the structure 44.

In this example, the second electrode 46 is the pull-off electrode and the electrode 48 supports the structure above the substrate 50. In the OTP mode described above, high adhesive forces are an advantage. The greater the area of overlap of the tip of the structure 44 and the underlying pull-in electrode 43, the more the adhesive forces will maintain contact between the structure 40 and the electrodes.

However, such a structure 40 can be used effectively in the MTP mode if it is not made from a high stiction material.

The micro-electromechanical structure of the present invention is preferably sealed in a low pressure cavity to permit operation and protect the structure 10. The sealing layers are typically thin capping layers which may be formed from oxides and nitride materials deposited using high temperature processes such as chemical vapour deposition (CVD) or using metal layers deposited by sputtering, evaporation of CVD.

1. A method of manufacturing a non-volatile memory bitcell, the method comprising the steps of:
depositing a first layer of conductive material on a substrate;
patterning and etching the first layer of conductive material to form three non-linearly disposed electrodes;
depositing a first layer of sacrificial material on the electrodes and the substrate;
providing an elongate cantilever structure on the first layer of sacrificial material such that the cantilever structure and at least a portion of each electrode overlap each other;
depositing a second layer of sacrificial material on the cantilever structure and the first layer of sacrificial material;
providing a capping layer on the second layer of sacrificial material and providing holes in the capping layer such that at least a portion of the second layer of sacrificial material is exposed;
removing the first and second layers of sacrificial material through the holes provided in the capping layer, thereby defining a cavity in which the cantilever structure is suspended.

2. The method of claim 1, wherein the step of providing the elongate cantilever structure further comprises the steps of:
depositing a second layer of conductive material on the first layer of sacrificial material;
patterning and etching the layer of conductive material such that it forms an elongate cantilever structure.

3. The method of claim 2, wherein the step of patterning and etching the layer of conductive material further comprises the step of:
patterning and etching the layer of conductive material into a U-shaped cantilever structure.

4. (canceled)

5. (canceled)

6. (canceled)

7. (canceled)

8. A nonvolatile memory bitcell comprising:
a substrate;
a first, second and third electrode, the electronics being co-planarly and non-linearly disposed on the substrate;
a cantilever structure disposed such that the cantilever structure and at least a portion of each electrode overlap each other, the non-volatile memory bitcell being arranged such that, in use, the application of a voltage between the first and second electrode pulls at least a portion of the cantilever structure toward the second electrode and the application of a voltage between the first and the third electrode pushed the at least one portion of the cantilever structure away from the second electrode.

9. The non-volatile memory bitcell of claim 8, wherein the cantilever structure is U-shaped.

10. (canceled)

11. (canceled)

12. The method of claim 1, wherein the electrodes are made from a group of materials selected from nickel, copper, chromium, cobalt, zinc, iron, titanium, aluminum, tantalum, ruthenium, platinum, and cobalt.

13. The method of claim 1, wherein the sacrificial layer is made from silicon-based materials.

14. The method of claim 1, wherein the sacrificial layer is made from carbon-based materials.

15. The method of claim 1, wherein the layer defining the cantilever structure comprises a group of materials selected from nickel, copper, chromium, cobalt, zinc, iron, titanium, aluminum, tantalum, ruthenium, and platinum.

16. The method of claim 1, wherein the layers of sacrificial material are removed through etching.
